(19) United States
(12) Patent Application Publication
(10) Pub. No.: US 2013/0168666 A1
(43) Pub. Date: Jul. 4, 2013

(54) SEMICONDUCTOR DEVICE AND METHOD OF FORMING THE SAME

(71) Applicants: Jing-Yi Yan, Hsinchu County (TW); Chen-Wei Lin, Kaohsiung City (TW); Chih-Chieh Hsu, Hsinchu City (TW); King-Yuan Ho, Hsinchu County (TW)

(72) Inventors: Jing-Yi Yan, Hsinchu County (TW); Chen-Wei Lin, Kaohsiung City (TW); Chih-Chieh Hsu, Hsinchu City (TW); King-Yuan Ho, Hsinchu County (TW)

(73) Assignee: INDUSTRIAL TECHNOLOGY RESEARCH INSTITUTE, Hsinchu (TW)

(21) Appl. No.: 13/433,311

(22) Filed: Mar. 29, 2012

(30) Foreign Application Priority Data
Dec. 30, 2011 (TW) 100149891

(51) Int. Cl. H01L 29/12; H01L 21/336

(52) U.S. Cl. 257/43; 438/104; 257/E29.068; 257/E21.409

(57) ABSTRACT

A semiconductor device is provided. A first semiconductor layer is disposed on a substrate and has a channel region and two doped regions beside the channel region. A first dielectric layer is disposed on the substrate and covers the first semiconductor layer. A gate is disposed on the first dielectric layer and corresponds to the channel region of the first semiconductor layer. A second dielectric layer is disposed on the first dielectric layer and covers the gate. A second semiconductor layer is disposed on the second dielectric layer and corresponds to the gate. The boundary of the second semiconductor layer does not exceed that of the gate. At least one first conductive plug penetrates through the first and second dielectric layers and contacts one doped region of the first semiconductor layer. At least one contact contacts the second semiconductor layer. A method of forming a semiconductor device is also provided.

### CROSS-REFERENCE TO RELATED APPLICATION

This application claims the priority benefit of Taiwan application serial no. 100149891, filed on Dec. 30, 2011. The entirety of the above-mentioned patent application is hereby incorporated by reference herein and made a part of this specification.

### TECHNICAL FIELD

The disclosure relates to a semiconductor device including low temperature polysilicon (LTPS) and metal oxide semiconductor (MOS) and a method of forming the same.

### BACKGROUND

A complementary metal oxide semiconductor (CMOS) device has the advantage of consuming power only when the device is required to switch on/off. Therefore, the CMOS device saves electricity and generates less heat. Further, many logic circuits also require the CMOS property to easily achieve their performance.

Generally speaking, the process temperature of a LTPS device is about 600° C. However, at least six photolithography and etching processes (PEPs) are required to fabricate the LTPS device. With ion implantation, annealing, hydrogenation processes used in combination, the process steps become very complicated. In addition, the threshold voltage (Vt) of the formed CMOS device and the leakage current during operation at 0 V are not easy to control, so that the CMOS device is not feasible due to its bad property. On the other hand, a high temperature polysilicon (HTPS) device is also formed through complicated process steps, and this technique cannot be applied to a flexible substrate due to the high process temperature.

### SUMMARY

Accordingly, the present disclosure provides a semiconductor device and a method of forming the same, in which less process steps, wider process window and lower process temperature are used to fabricate the semiconductor device with excellent CMOS property.

The present disclosure provides a semiconductor device. A substrate has a first area and a second area. A first semiconductor layer is disposed on the substrate in the first area and has a channel region and two doped region located beside the channel region. A first dielectric layer is disposed on the substrate in the first area and in the second area and covers the first semiconductor layer. A first gate and a second gate are disposed on the first dielectric layer respectively in the first area and in the second area, wherein the first gate corresponds to the channel region of the first semiconductor layer. A second dielectric layer is disposed on the first dielectric layer in the first area and in the second area and covers the first gate and the second gate. A second semiconductor layer is disposed on the second dielectric layer and corresponds to the second gate, wherein a boundary of the second semiconductor layer does not exceed a boundary of the second gate. Two first conductive plugs penetrate through the first dielectric layer and the second dielectric layer, are disposed beside the first gate and respectively contact the doped regions of the first semiconductor layer. Two contacts (such as metal patterns or conductive plugs) are located in the second area and contact the second semiconductor layer.

The present disclosure further provides a semiconductor device. A first semiconductor layer is disposed on a substrate and has a channel region and two doped regions located beside the channel region. A first dielectric layer is disposed on the substrate and covers the first semiconductor layer. A gate is disposed on the first dielectric layer, wherein the gate corresponds to the channel region of the first semiconductor layer. A second dielectric layer is disposed on the first dielectric layer and covers the gate. A second semiconductor layer is disposed on the second dielectric layer and corresponds to the gate, wherein a boundary of the second semiconductor layer does not exceed a boundary of the gate. At least one first conductive plug penetrates through the first dielectric layer and the second dielectric layer and contacts one of the doped regions of the first semiconductor layer. At least one contact (metal pattern or conductive plug) contacts the second semiconductor layer.

The present disclosure also provides a method of forming a semiconductor device. A substrate having a first area and a second area is provided. A first semiconductor layer is formed on the substrate in the first area. A first dielectric layer is formed on the substrate in the first area and in the second area, and the first dielectric layer covers the first semiconductor layer. A first gate and a second gate are formed on the first dielectric layer respectively in the first area and in the second area. An ion implantation process is preformed to the first semiconductor layer by using the first gate as a mask, so as to form two doped regions in the first semiconductor layer. A second dielectric layer is formed on the substrate in the first area and in the second area, and the second dielectric layer covers the first gate and the second gate. A second semiconductor layer is formed on the second dielectric layer, wherein the second semiconductor layer corresponds to the second gate, and a boundary of the second semiconductor layer does not exceed a boundary of the second gate. A patterning step is performed to form two first openings in the first dielectric layer and the second dielectric layer, wherein the first openings respectively expose the doped regions of the first semiconductor layer. A metal layer is formed on the substrate, wherein the metal layer fills in the first openings to form a first conductive plug in each first opening, and the metal layer contacts a portion of an upper surface of the second semiconductor layer.

The present disclosure further provides a method of forming a semiconductor device. A first semiconductor layer is formed on a substrate. A first dielectric layer is formed on the substrate, and the first dielectric layer covers the first semiconductor layer. A gate is formed on the first dielectric layer. An ion implantation process is performed to the first semiconductor layer by using the gate as a mask, so as to form two doped regions in the first semiconductor layer. A second dielectric layer is formed on the substrate, and the second dielectric layer covers the gate. A second semiconductor layer is formed on the second dielectric layer, wherein the second semiconductor layer corresponds to the gate, and a boundary of the second semiconductor layer does not exceed a boundary of the gate. A patterning step is performed to four at least one first opening in the first dielectric layer and the second dielectric layer, and the first opening exposes one of the doped regions of the first semiconductor layer. A metal layer is formed on the substrate, wherein the metal layer fills in the first opening to form a first conductive plug in the first opening, and the metal layer at least contacts a portion of an upper surface of the second semiconductor layer.

In view of the above, in the disclosure, only five PEPs are used to complete a semiconductor structure having an N-type device and a P-type device. Therefore, the number of processes is significantly reduced, the process cost is lower and the competitive advantage is achieved. Besides, the process temperature used in the method of the disclosure does not exceed 450° C. Accordingly, the method can be applied to a glass or a flexible substrate, so as to further enhance the variety and performance of the circuit design.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIGS. 1A to 1E schematically illustrate cross-sectional views of a method of forming a semiconductor device according to a first embodiment of the disclosure.

FIGS. 2A to 2D schematically illustrate cross-sectional views of a method of forming a semiconductor device according to a second embodiment of the disclosure.

FIGS. 3A to 3B schematically illustrate cross-sectional views of a method of forming a semiconductor device according to a third embodiment of the disclosure.

FIGS. 4A to 4E schematically illustrate cross-sectional views of a method of forming a semiconductor device according to a fourth embodiment of the disclosure.

FIG. 4E-1 schematically illustrates a cross-sectional view of a semiconductor device according to the fourth embodiment of the disclosure.

FIGS. 5A to 5D schematically illustrate cross-sectional views of a method of forming a semiconductor device according to a fifth embodiment of the disclosure.

FIG. 5D-1 schematically illustrates a cross-sectional view of a semiconductor device according to the fifth embodiment of the disclosure.

FIGS. 6A to 6B schematically illustrate cross-sectional views of a method of forming a semiconductor device according to a sixth embodiment of the disclosure.

### DETAILED DESCRIPTION OF DISCLOSED EMBODIMENTS

### First embodiment

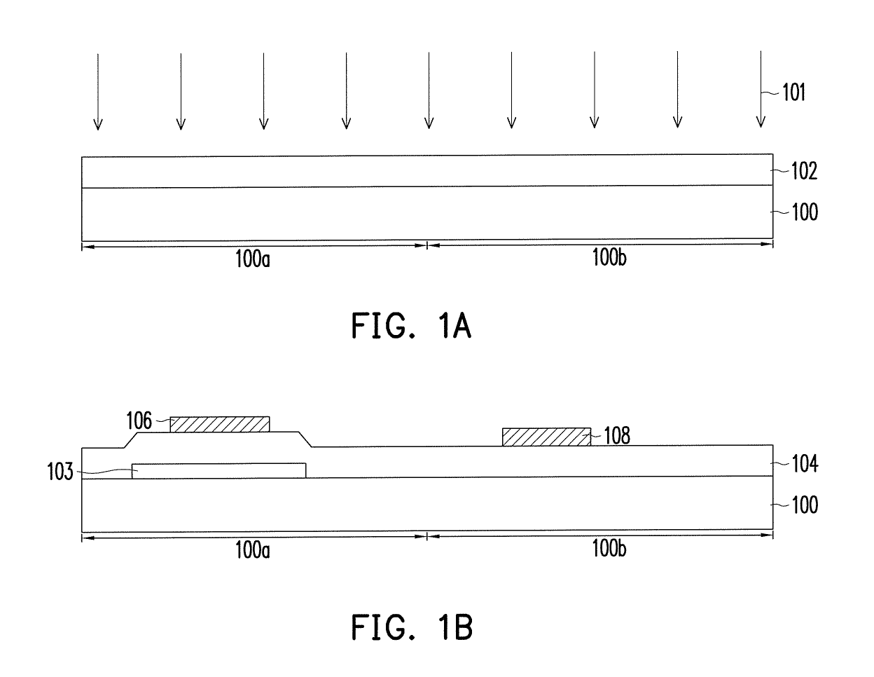

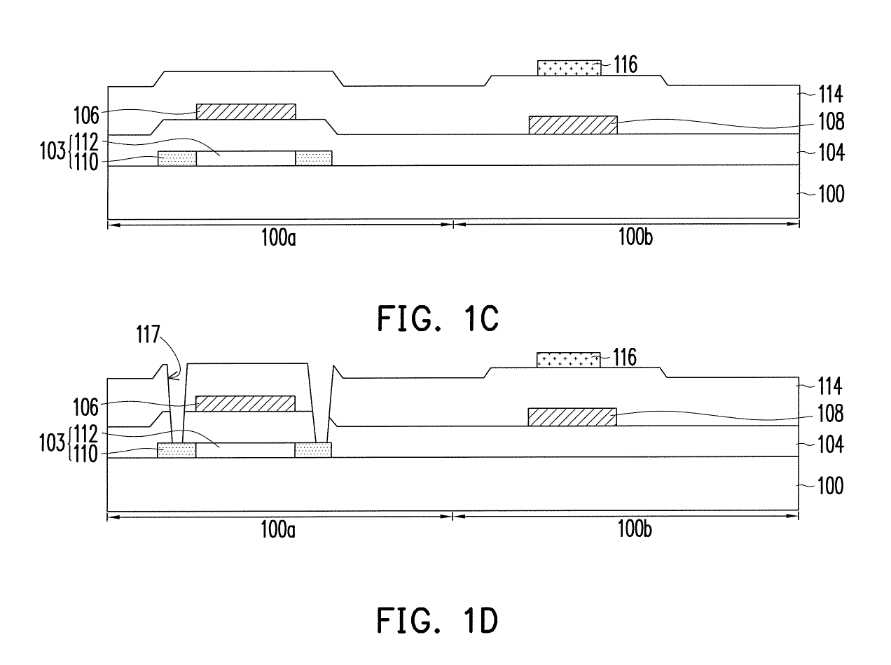

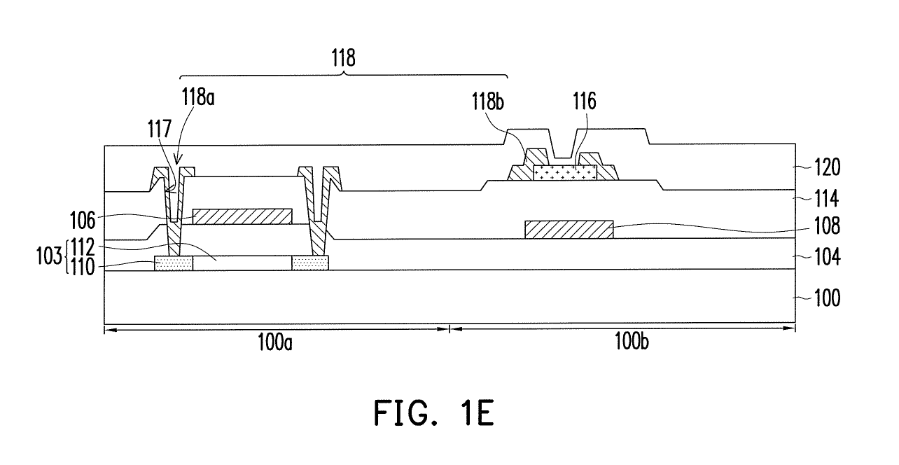

FIGS. 1A to 1E schematically illustrate cross-sectional views of a method of forming a semiconductor device according to a first embodiment of the disclosure.

Referring to FIG. 1A, a substrate 100 is provided. The substrate 100 can be a hard substrate or a flexible substrate. The hard substrate is a glass substrate or a silicon substrate, for example. The flexible substrate is a metal sheet or a plastic substrate, for example. The substrate 100 has a first area 100a and a second area 100b. In an embodiment, the first area 100a is a P-type device area, and the second area 100b is an N-type device area, for example.

Referring to FIGS. 1A and 1B, a semiconductor layer 103 is formed on the substrate 100 in the first area 100a. The material of the semiconductor layer 103 of the disclosure includes low temperature polysilicon (LTPS). The process temperature of the semiconductor layer 103 does not exceed 450° C., which is applicable to a flexible substrate. In an embodiment, the process temperature is equal to or less than 450° C.

In another embodiment, the process temperature is equal to or less than 400° C. The method of forming the semiconductor layer 103 includes forming an amorphous silicon layer 102 on the substrate 100 in the first area 100a and in the second area 100b. Thereafter, as shown in FIG. 1A, a crystallization process 101 is performed to the amorphous silicon layer 102, so as to form a polysilicon layer. The crystallization process 101 includes an excimer laser annealing (ELA) process and a metal induced crystallization (MIC) process. Afterwards, a patterned photoresist layer (not shown) is formed on the substrate 100. The polysilicon layer is then patterned by using the patterned photoresist layer as a mask, so as to form the semiconductor layer 103 on the substrate 100 in the first area 100a, as shown in FIG. 1B.

Referring to FIG. 1B, a dielectric layer 104 is formed on the substrate 100 in the first area 100a and in the second area 100b, and the dielectric layer 104 covers the semiconductor layer 103. The material of the dielectric layer 104 can be silicon oxide, silicon nitride, silicon oxynitride, a high-k material or a suitable organic material, and the forming method thereof includes performing a chemical vapour deposition (CVD) process, a physical vapour deposition (PVD) process or a spin coating method etc. Afterwards, a gate 106 and a gate 108 are formed on the dielectric layer 104 respectively in the first area 100a and in the second area 100b. The method of forming the gate 106 and the gate 108 includes sequentially forming a gate metal layer and a patterned photoresist layer (not shown) on the dielectric layer 104. The material of the gate metal layer can be Mo, W, Al, Ti or an alloy system containing one of said metals, and the forming method thereof includes performing a PVD process. Thereafter, the gate metal layer is patterned by using the patterned photoresist layer as a mask.

Referring to FIG. 1C, an ion implantation process is performed to the semiconductor layer 103 by using the gate 106 as a mask, so as to form two doped regions 110 in the semiconductor layer 103. The ion implantation process is a self-aligned process, and a channel region 112 corresponding to the gate 106 and two doped regions 110 located beside the channel region 112 are formed in the semiconductor layer 103. In an embodiment, when the first area 100a is a P-type device area, the commonly used dopant is boron ion, for example.

In the described method in FIGS. 1B and 1C, the channel region 112 of the semiconductor layer 103 is an undoped region. However, the present disclosure is not limited thereto. In another embodiment (not shown), after the semiconductor layer 103 is formed, an ion implantation process is performed to the semiconductor layer 103 before the gate 106 is formed. That is, the channel region 112 of the semiconductor layer 103 can be a doped region. It is appreciated by persons skilled in the art that the dopant concentration of the channel region 112 can be adjusted upon the process requirements. In other words, the dopant concentration of the central channel region 112 can be the same or different from that of the two edge doped regions 110.

Thereafter, a dielectric layer 114 is formed on the substrate 100 in the first area 100a and in the second area 100b, and the dielectric layer 114 covers the gate 106 and the gate 108. The material of the dielectric layer 114 can be silicon oxide, silicon nitride, silicon oxynitride, a high-k material or a suitable organic material, and the forming method thereof includes performing a CVD process, a PVD process or a spin coating method etc.

Afterwards, a semiconductor layer 116 corresponding to the gate 108 is formed on the dielectric layer 114, and the boundary of the semiconductor layer 116 does not exceed the boundary of the gate 108. That is, the semiconductor layer 116 is “island-in” the gate 108. In an embodiment, the boundary of the semiconductor layer 116 is within that of the gate 108, as shown in FIG. 1C. In another embodiment (not shown), the boundary of the semiconductor layer 116 can be aligned with that of the gate 108. The material of the semiconductor layer 116 includes metal oxide semiconductor, such as ZnO, InOx, SnOx, GaOx, AlOx or a combination thereof. The method of forming the semiconductor layer 116 includes sequentially forming a semiconductor material layer and a patterned photoresist layer (not shown) on the dielectric layer 114. Afterwards, the semiconductor material layer is patterned by using the patterned photoresist layer as a mask.

Referring to FIG. 1D, a patterning step is performed to Bonn two openings 117 in the dielectric layer 104 and the dielectric layer 114. The openings 117 penetrate through the dielectric layer 104 and the dielectric layer 114, are disposed beside the gate 106 and respectively expose the doped regions 110 of the semiconductor layer 103. The patterning step includes forming a patterned photoresist layer (not shown) on the dielectric layer 114. Thereafter, the dielectric layer 104 and the dielectric layer 114 are patterned by using the patterned photoresist layer as a mask.

Referring to FIG. 1E, a metal layer 118 is formed on the substrate 100. The metal layer 118 fills in the openings 117 to form a conductive plugs 118a in each opening 117, and the metal layer 118 contacts a portion of the upper surface of the semiconductor layer 116. Specifically, the metal layer 118 has two metal patterns 118b, and the metal patterns 118b respectively cover two edges of the top surface of the semiconductor layer 116 while expose the central region of the top surface of the semiconductor layer 116. Besides, the metal patterns 118b further cover the opposite sidewalls of the semiconductor layer 116 respectively. The material of the metal layer 118 is Ti, Al or Ti—Al alloy, for example. The method of forming the metal layer 118 includes sequentially forming a metal material layer and a patterned photoresist layer (not shown) on the dielectric layer 114. Thereafter, the metal material layer is patterned by using the patterned photoresist layer as a mask.

Thereafter, a dielectric layer 120 is formed on the substrate 100 in the first area 100a and in the second area 100b. The dielectric layer 120 covers the conductive plugs 118a, and covers the metal patterns 118b and the exposed top surface of the semiconductor layer 116. The material of the dielectric layer 120 can be silicon oxide, silicon nitride, silicon oxynitride, a high-k material or a suitable organic material, and the forming method thereof includes performing a CVD process, a PVD process or a spin coating method etc. Besides, the dielectric layer 104, the dielectric layer 114 and the dielectric layer 120 can include the same or different materials. The semiconductor device of the first embodiment is thus completed.

In the first embodiment, only five photolithography and etching processes (PEPs) are required to complete a CMOS structure, wherein a P-type device is formed in the first area 100a, and an N-type device is formed in the second area 100b. In details, the semiconductor layer 103 is formed through the first PEP; the gate 106 and the gate 108 are formed through the second PEP; the semiconductor layer 116 is formed through the third PEP; the openings 117 are formed through the fourth PEP; and the metal layer 118 is formed through the fifth PEP. Therefore, by forming a P-type bottom gate device in the first area 100a and forming an N-type top gate device in the second area 100b, the number of processes can be reduced, the process cost can be lower and the competitive advantage can be achieved.

The semiconductor structure of the first embodiment is illustrated below with reference to FIG. 1E. A substrate 100 has a first area 100a and a second area 100b. A semiconductor layer 103 is disposed on the substrate 100 in the first area 100a and has a channel region 112 and two doped regions 110 located beside the channel region 112. A dielectric layer 104 is disposed on substrate 100 in the first area 100a and in the second area 100b, and covers the semiconductor layer 103. A gate 106 and a gate 108 are disposed on the dielectric layer 104 respectively in the first area 100a and in the second area 100b, wherein the gate 106 corresponds to the channel region 112 of the semiconductor layer 103. A dielectric layer 114 is disposed on the substrate 100 in the first area 100a and in the second area 100b, and covers the gate 106 and the gate 108. A semiconductor layer 116 is disposed on the dielectric layer 114 and corresponds to the gate 108, wherein the boundary of the semiconductor layer 116 does not exceed the boundary of the gate 108. Two conductive plugs 118a penetrate through the dielectric layer 104 and the dielectric layer 114, are disposed beside the gate 106 and respectively contact the doped regions 110 of the semiconductor layer 103. Two metal patterns 118b are disposed respectively at two edges of the semiconductor layer 116 and expose a portion of the upper surface of the semiconductor layer 116. A dielectric layer 120 is disposed on the dielectric layer 114 in the first area 100a and in the second area 100b, covers the conductive plugs 118a, and covers the metal patterns 118b and the exposed top surface of the semiconductor layer 116.

### Second Embodiment

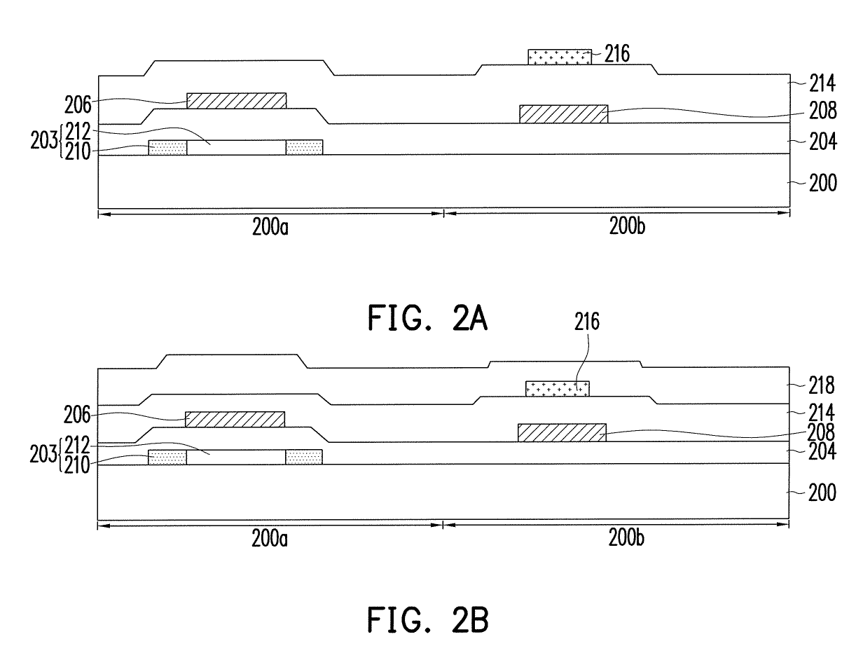

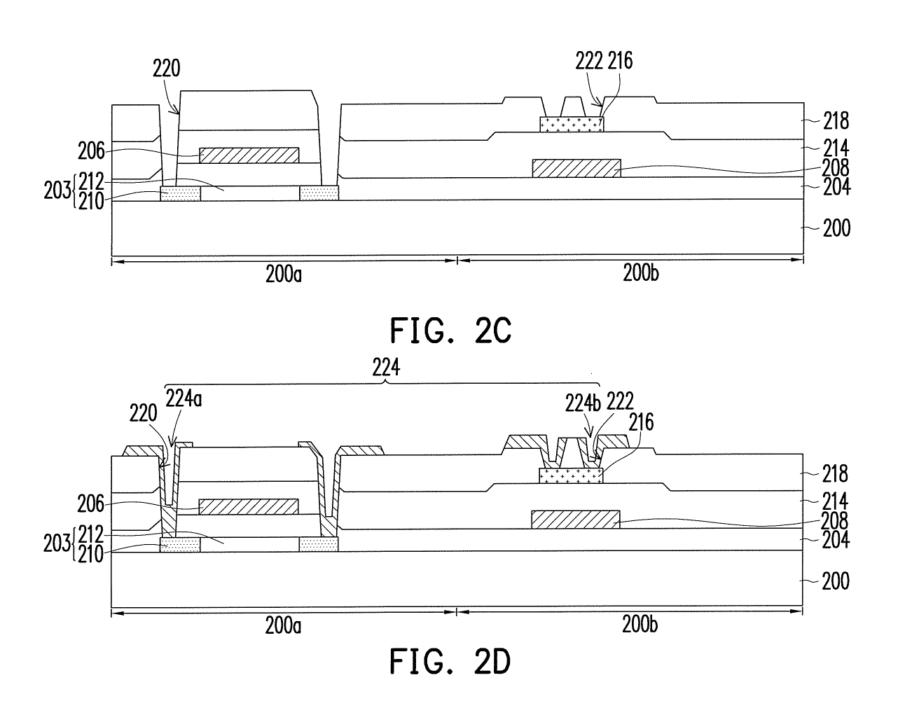

FIGS. 2A to 2D schematically illustrate cross-sectional views of a method of forming a semiconductor device according to a second embodiment of the disclosure. The second embodiment is similar to the first embodiment, the difference between them is illustrated in the following, and the similarity is not iterated herein.

Referring to FIG. 2A, a substrate 200 is provided. The substrate 200 has a first area 200a and a second area 200b. In an embodiment, the first area 200a is a P-type device area, and the second area 200b is an N-type device area, for example. Thereafter, a semiconductor layer 203 is formed on the substrate 200 in the first area 200a. Afterwards, a dielectric layer 204 is formed on the substrate 200 in the first area 200a and in the second area 200b, and the dielectric layer 204 covers the semiconductor layer 203. A gate 206 and a gate 208 are then formed on the dielectric layer 204 respectively in the first area 200a and in the second area 200b. Further, an ion implantation process is preformed to the semiconductor layer 203 by using the gate 206 as a mask, so as to form two doped regions 210 in the semiconductor layer 203. The ion implantation process is a self-aligned process, and a channel region 212 corresponding to the gate 206 and two doped regions 210 located beside the channel region 212 are formed in the semiconductor layer 203. Thereafter, a dielectric layer 214 is formed on the substrate 200 in the first area 200a and in the second area 200b, and the dielectric layer 214 covers the gate 206 and the gate 208. Afterwards, a semiconductor layer 216 is formed on the dielectric layer 214. The semiconductor layer 216 corresponds to the gate 208, and the boundary of the semiconductor layer 216 does not exceed the boundary of the gate 208. That is, the semiconductor layer 216 is “island-in” the gate 208. The materials and forming methods of the components in FIG. 2A are similar to those in FIGS. 1A to 1C, and the details are not iterated herein.

Referring to FIG. 2B, a dielectric layer 218 is formed on the substrate 200 in the first area 200a and in the second area 200b, and the dielectric layer 218 covers the semiconductor layer 216. The material of the dielectric layer 218 can be silicon oxide, silicon nitride, silicon oxynitride, a high-k material or a suitable organic material, and the forming method thereof includes performing a CVD process, a PVD process or a spin coating method etc. Besides, the dielectric layer 204, the dielectric layer 214 and the dielectric layer 218 include the same or different materials.

Referring to FIG. 2C, a patterning step is performed to form two openings 220 and two openings 222 in the dielectric layer 204, the dielectric layer 214 and the dielectric layer 218. The openings 220 penetrate through the dielectric layer 204, the dielectric layer 214 and the dielectric layer 218, and respectively expose the doped regions 210 of the semiconductor layer 203. The openings 222 penetrate through the dielectric layer 218 and expose a portion of the upper surface of the semiconductor layer 216.

Referring to FIG. 2D, a metal layer 224 is formed on the substrate 200. The metal layer 224 fills in the openings 220 and the openings 222, so as to form a conductive plug 224a in each opening 220 and form a conductive plug 224b in each opening 222. Accordingly, the metal layer 224 contacts the portion of the upper surface of the semiconductor layer 216; that is, the conductive plugs 224b of the metal layer 224 contacts the portion of the upper surface of the semiconductor layer 216. The material and forming method of the metal layer 224 have been described in the first embodiment, and the details are not iterated herein.

The semiconductor device of the second embodiment is thus completed. As similar to the case of the first embodiment, only five PEPs are required to fabricate the CMOS structure of the second embodiment.

The semiconductor structure of the second embodiment is illustrated below with reference to FIG. 2D. A substrate 200 has a first area 200a and a second area 200b. A semiconductor layer 203 is disposed on the substrate 200 in the first area 200a and has a channel region 212 and two doped regions 210 located beside the channel region 212. A dielectric layer 204 is disposed on the substrate 200 in the first area 200a and in the second area 200b, and covers the semiconductor layer 203. A gate 206 and a gate 208 are disposed on the dielectric layer 204 respectively in the first area 200a and in the second area 200b, wherein the gate 206 corresponds to the channel region 212 of the semiconductor layer 203. A dielectric layer 214 is disposed on the substrate 200 in the first area 200a and in the second area 200b, and covers the gate 206 and the gate 208. A semiconductor layer 216 is disposed on the dielectric layer 214 and corresponds to the gate 208, wherein the boundary of the semiconductor layer 216 does not exceed the boundary of the gate 208. A dielectric layer 218 is disposed on the dielectric layer 214 in the first area 200a and in the second area 200b, and covers the semiconductor layer 216. Two conductive plugs 224a penetrate through the dielectric layer 204, the dielectric layer 214 and the dielectric layer 218, are disposed beside the gate 206 and respectively contact the doped regions 210 of the semiconductor layer 203. Two conductive plugs 224b penetrate through the dielectric layer 218 and contact the semiconductor layer 216.

### Third Embodiment

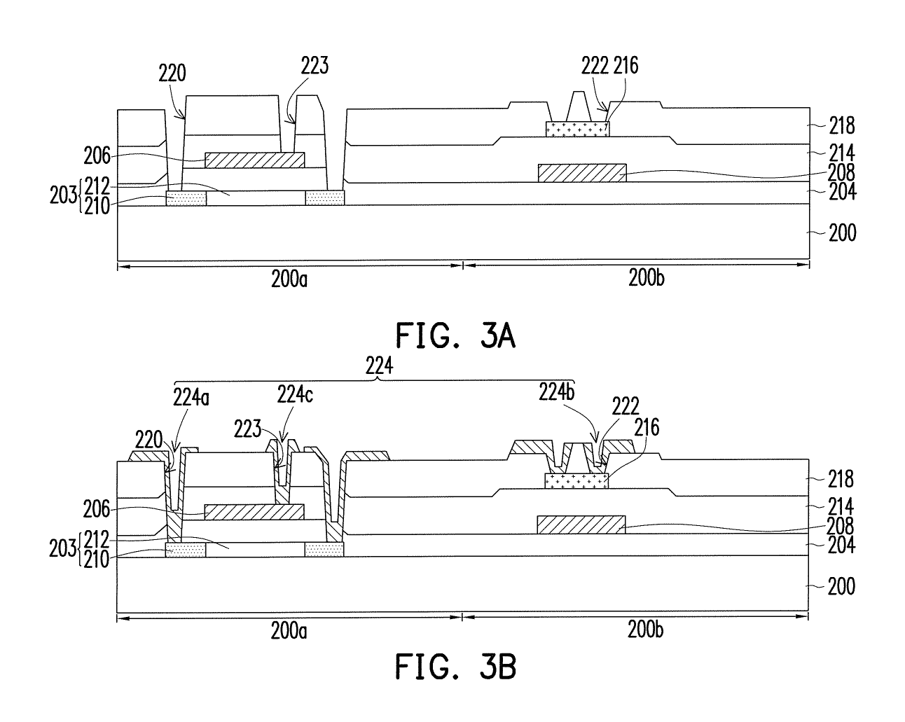

FIGS. 3A to 3B schematically illustrate cross-sectional views of a method of forming a semiconductor device according to a third embodiment of the disclosure. The third embodiment is similar to the second embodiment, the difference between them is illustrated in the following, and the similarity is not iterated herein.

First, an intermediate structure of FIG. 2B is provided. Thereafter, referring to FIG. 3A, a perform patterning step is performed to form two openings 220, two openings 222 and one opening 223 in the dielectric layer 204, the dielectric layer 214 and the dielectric layer 218. The openings 220 penetrate through the dielectric layer 204, the dielectric layer 214 and the dielectric layer 218, and respectively expose the doped regions 210 of the semiconductor layer 203. The openings 222 penetrate through the dielectric layer 218 and expose a portion of the upper surface of the semiconductor layer 216. The opening 223 penetrates through the dielectric layer 214 and the dielectric layer 218, and exposes a portion of the gate 206.

Referring to FIG. 3B, a metal layer 224 is formed on the substrate 200. The metal layer 224 fills in the openings 220, the openings 222 and the opening 223, so as to form a conductive plug 224a in each opening 220, form a conductive plug 224b in each opening 222 and form a conductive plug 224c in the opening 223. Accordingly, the metal layer 224 contacts a portion of the upper surface of the semiconductor layer 216; that is, the conductive plugs 224b of the metal layer 224 contact the portion of the upper surface of the semiconductor layer 216. It is noted that conductive plug 224c is electrically connected to one of the conductive plugs 224b through a wire (not shown). Besides, the conductive plug 224c is electrically connected to the gate 206. That is, the gate 206 is electrically connected to one of the conductive plugs 224b. The material and forming method of the metal layer 224 have been described in the first embodiment, and the details are not iterated herein.

The semiconductor device of the third embodiment is thus completed. As similar to the case of the second embodiment, only five PEPs are required to fabricate the CMOS structure of the third embodiment.

In the third embodiment, the gate 206 is electrically connected to one of the conductive plugs 224b through, for example, the conductive plug 224c, and this structure can serve as an active matrix organic light emitting diode (AMOLED), wherein the P-type device in the first area 200a serves as an OLED driver transistor, and the N-type device in the second area 200b serves as a switch transistor.

The semiconductor structure of the third embodiment is illustrated below with reference to FIG. 3B. As compared with the structure of the second embodiment, the structure of the third embodiment further comprises a conductive plug 224c. The conductive plug 224c penetrates through the dielectric layer 214 and the dielectric layer 218 and contacts the gate 206. Besides, the conductive plug 224c is electrically connected to one of the conductive plugs 224b. Accordingly, the gate 206 is electrically connected to one of the conductive plugs 224b.

The above-mentioned embodiments in which the first area 100a is a P-type device area and the second area 100b is an N-type device area are provided for illustration purposes, and are not construed as limiting the present disclosure. It is appreciated by persons skilled in the art that the first area 100a can be an N-type device area, and the second area 100b can be a P-type device area.

Besides, in the first to third embodiments, the P-type device and the N-type device are disposed in a horizontal arrangement. However, the present disclosure is not limited thereto. The embodiments in which the P-type device and the N-type device are disposed in a vertical arrangement are illustrated in the following.

### Fourth Embodiment

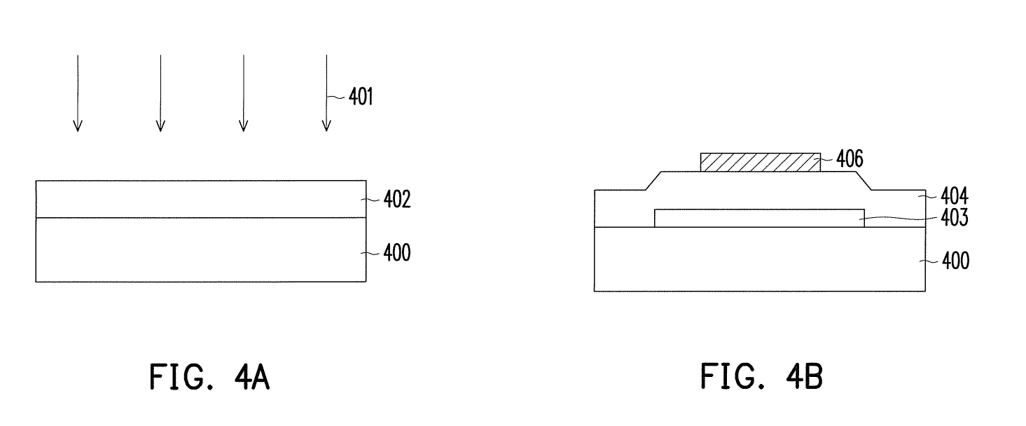

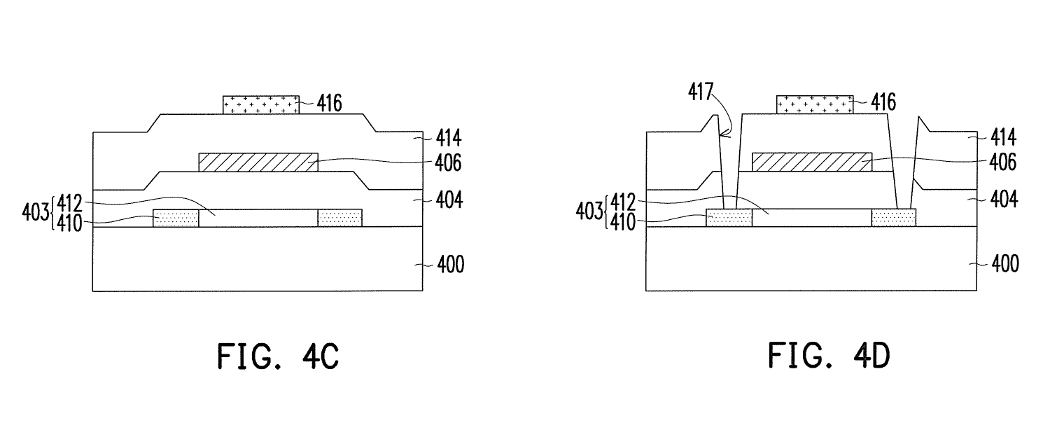

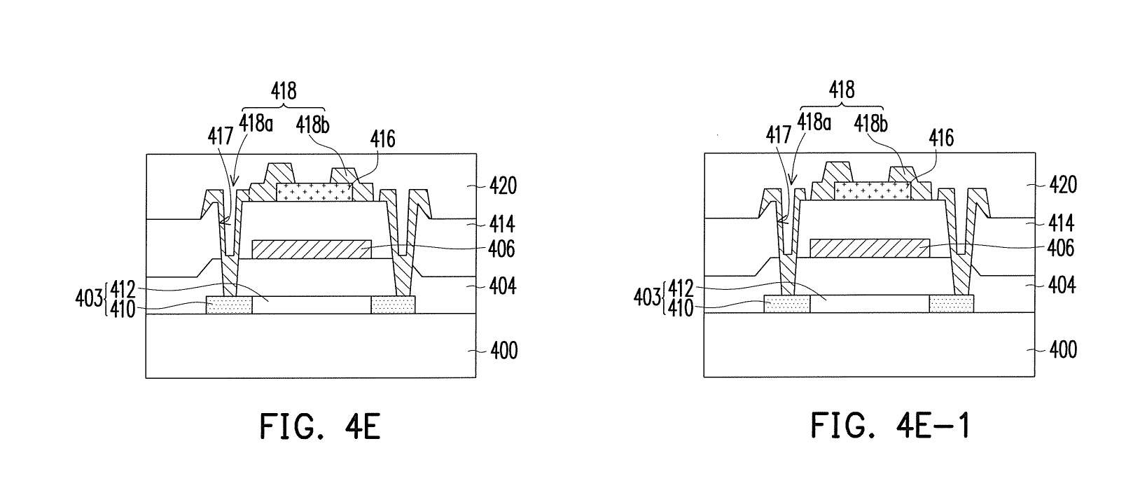

FIGS. 4A to 4E schematically illustrate cross-sectional views of a method of forming a semiconductor device according to a fourth embodiment of the disclosure.

Referring to FIG. 4A, a substrate 400 is provided. The substrate 400 can be a hard substrate or a flexible substrate. The hard substrate is a glass substrate or a silicon substrate, for example. The flexible substrate is a metal sheet or a plastic substrate, for example.

Referring to FIGS. 4A and 4B, a semiconductor layer 403 is formed on the substrate 400. The material of the semiconductor layer 403 includes low temperature polysilicon (LTPS). The process temperature of the semiconductor layer 403 does not exceed 450° C., which is applicable to a flexible substrate. The method of forming the semiconductor layer 403 includes forming an amorphous silicon layer 402 on the substrate 400. Thereafter, as shown in FIG. 4A, a crystallization process 401 is performed to the amorphous silicon layer 402, so as to form a polysilicon layer. The crystallization process 401 includes an excimer laser annealing (ELA) process and a metal induced crystallization (MIC) process. Afterwards, a patterned photoresist layer (not shown) is formed on the substrate 400. The polysilicon layer is then patterned by using the patterned photoresist layer as a mask, so as to form the semiconductor layer 403 on the substrate 400.

Referring to FIG. 4B, a dielectric layer 404 is formed on the substrate 400, and the dielectric layer 404 covers the semiconductor layer 403. The material of the dielectric layer 404 can be silicon oxide, silicon nitride, silicon oxynitride, a high-k material or a suitable organic material, and the forming method thereof includes performing a CVD process, a PVD process or a spin coating method etc. Afterwards, a gate 406 is formed on the dielectric layer 404. The method of forming the gate 406 includes sequentially forming a gate metal layer and a patterned photoresist layer (not shown) on the dielectric layer 404. The gate metal layer can be Mo, W, Al, Ti or an alloy system containing one of said metals, and the forming method thereof includes performing a PVD process. Thereafter, the gate metal layer is patterned by using the patterned photoresist layer as a mask.

Referring to FIG. 4C, an ion implantation process is performed to the semiconductor layer 403 by using the gate 406 as a mask, so as to form two doped regions 410 in the semiconductor layer 403. The ion implantation process is a self-aligned process, and a channel region 412 corresponding to the gate 406 and two doped regions 410 located beside the channel region 412 are formed in the semiconductor layer 403. In an embodiment, the commonly used dopant is boron ion, for example.

Thereafter, a dielectric layer 414 is formed on the substrate 400, and the dielectric layer 414 covers the gate 406. The material of the dielectric layer 414 can be silicon oxide, silicon nitride, silicon oxynitride, a high-k material or a suitable organic material, and the forming method thereof includes performing a CVD process, a PVD process or a spin coating method etc.

Afterwards, a semiconductor layer 416 is formed on the dielectric layer 414. The semiconductor layer 416 corresponds to the gate 406, and the boundary of the semiconductor layer 416 does not exceed the boundary of the gate 406. That is, semiconductor layer 416 is “island-in” the gate 406. In an embodiment, the boundary of the semiconductor layer 416 is within that of the gate 406, as shown in FIG. 4C. In another embodiment (not shown), the boundary of the semiconductor layer 416 can be aligned with that of the gate 406. The material of the semiconductor layer 416 includes metal oxide semiconductor, such as ZnO, InOx, SnOx, GaOx, AlOx or a combination thereof The method of forming the semiconductor layer 416 includes sequentially forming a semiconductor material layer and a patterned photoresist layer (not shown) on the dielectric layer 414. Afterwards, the semiconductor material layer is patterned by using the patterned photoresist layer as a mask.

Referring to FIG. 4D, a patterning step is performed to form two openings 417 in the dielectric layer 404 and the dielectric layer 414. The openings 417 penetrate through the dielectric layer 404 and the dielectric layer 414, are disposed beside the gate 406 and respectively expose the doped regions 410 of the semiconductor layer 403. The patterning step includes forming a patterned photoresist layer (not shown) on the dielectric layer 414. Thereafter, the dielectric layer 404 and the dielectric layer 414 are patterned by using the patterned photoresist layer as a mask.

Referring to FIG. 4E, a metal layer 418 is formed on the substrate 400. The metal layer 418 fills in the openings 417 to form a conductive plug 418a in each opening 417, and the metal layer 418 contacts a portion of the upper surface of the semiconductor layer 416. Specifically, the metal layer 418 has two metal patterns 418b, the metal patterns 418b respectively cover two edges of the top surface of the semiconductor layer 416 while expose the central region of the top surface of the semiconductor layer 416. Besides, the metal patterns 418b further cover the opposite sidewalls of the semiconductor layer 416 respectively. The material of the metal layer 418 is Ti, Al or Ti—Al alloy, for example. The method of forming the metal layer 418 includes sequentially forming a metal material layer and a patterned photoresist layer (not shown) on the dielectric layer 414. Thereafter, the metal material layer is patterned by using the patterned photoresist layer as a mask.

Thereafter, a dielectric layer 420 is formed on the substrate 400. The dielectric layer 420 covers the metal patterns 418b and the exposed top surface of the semiconductor layer 416, and covers the conductive plugs 418a. The material of the dielectric layer 420 can be silicon oxide, silicon nitride, silicon oxynitride, a high-k material or a suitable organic material, and the forming method thereof includes performing a CVD process, a PVD process or a spin coating method etc. Besides, the dielectric layer 404, the dielectric layer 414 and the dielectric layer 420 include the same or different materials.

The semiconductor device of the fourth embodiment is thus completed. The structure of the fourth embodiment can serve as a CMOS inverter, wherein the lower structure is a P-type device, the upper structure is an N-type device, and the P-type device and the N-type device share the gate 406. In an embodiment, one of the conductive plugs 418a is electrically connected to one of the metal patterns 418b (as shown in FIG. 4E), and the lower P-type device and the upper N-type device can be driven simultaneously. In another embodiment, the conductive plugs 418a are not electrically connected to the metal patterns 418b (as shown in FIG. 4E-1), and the lower P-type device and the upper N-type device can be driven separately.

In the fourth embodiment, only five PEPs are required to fabricate a CMOS inverter. In details, the semiconductor layer 403 is formed through the first PEP; the gate 406 is formed through the second PEP; the semiconductor layer 416 is formed through the third PEP; the openings 417 are formed through the fourth PEP; and the metal layer 418 are formed through the fifth PEP. Therefore, by forming a lower P-type device and an upper N-type device on the 400, the number of processes can be reduced, the process cost can be lower and the competitive advantage can be achieved.

The semiconductor structure of the fourth embodiment is illustrated below with reference to FIGS. 4E and 4E-1. A semiconductor layer 403 is disposed on a substrate 400 and has a channel region 412 and two doped regions 410 located beside the channel region 412. A dielectric layer 404 is disposed on the substrate 400 and covers the semiconductor layer 403. A gate 406 is disposed on the dielectric layer 404, wherein the gate 406 corresponds to the channel region 412 of the semiconductor layer 403. A dielectric layer 414 is disposed on the substrate 400 and covers the gate 406. A semiconductor layer 416 is disposed on the dielectric layer 414 and corresponds to the gate 406, wherein the boundary of the semiconductor layer 416 does not exceed the boundary of the gate 406. Two conductive plugs 418a penetrate through the dielectric layer 404 and the dielectric layer 414, are disposed beside the gate 406 and respectively contact the doped regions 410 of the semiconductor layer 403. Two metal patterns 418b are respectively disposed at two edges of the top surface of the semiconductor layer 416 while expose the central region of the top surface of the semiconductor layer 406. A dielectric layer 420 is disposed on the dielectric layer 414, covers the conductive plugs 418a and covers the metal patterns 418b and the exposed top surface of the semiconductor layer 416. In an embodiment, one of the conductive plugs 418a is electrically connected to one of the metal patterns 418b, as shown in FIG. 4E. In another embodiment, the conductive plugs 418a are not electrically connected to the metal patterns 418b, as shown in 4E-1.

### Fifth Embodiment

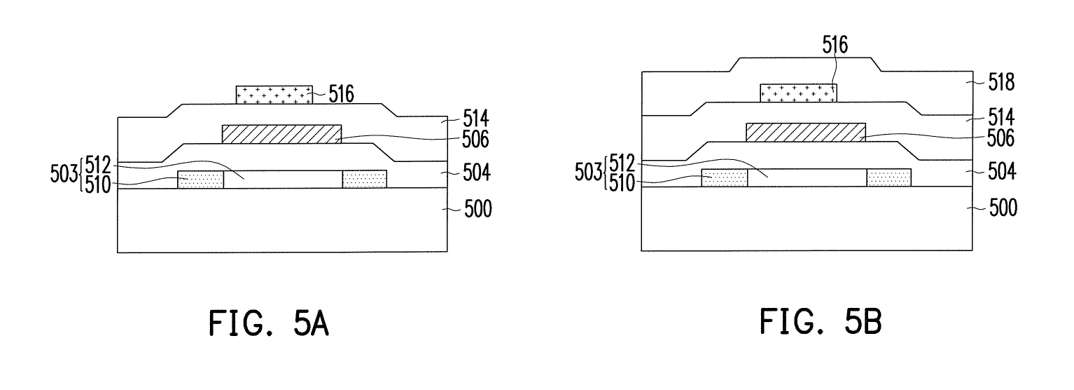

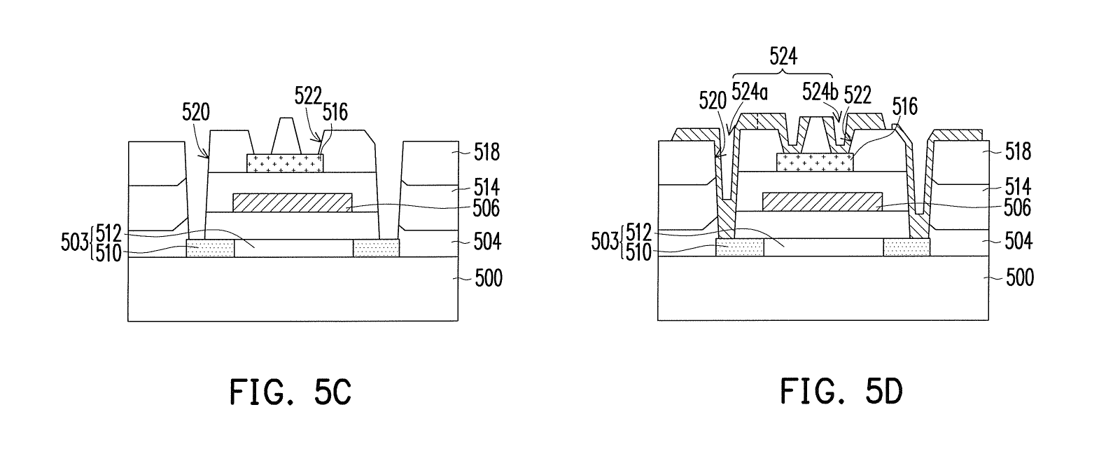

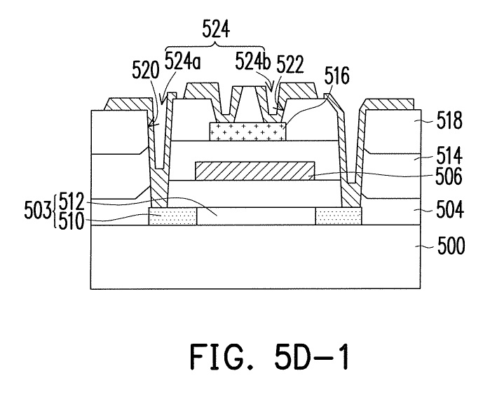

FIGS. 5A to 5D schematically illustrate cross-sectional views of a method of forming a semiconductor device according to a fifth embodiment of the disclosure. The fifth embodiment is similar to the fourth embodiment, the difference between them is illustrated in the following, and the similarity is not iterated herein.

Referring to FIG. 5A, a substrate 500 is provided. Afterwards, a semiconductor layer 503 is formed on the substrate 500. Thereafter, a dielectric layer 504 is formed on the substrate 500, and the dielectric layer 504 covers the semiconductor layer 503. A gate 506 is then formed on the dielectric layer 504. Further, an ion implantation process is performed to the semiconductor layer 503 by using the gate 506 as a mask, so as to form two doped regions 510 in the semiconductor layer 503. The ion implantation process is a self-aligned process, and a channel region 512 corresponding to the gate 506 and two doped regions 510 located beside the channel region 512 are formed in the semiconductor layer 503. Thereafter, a dielectric layer 514 is formed on the substrate 500, and the dielectric layer 514 covers the gate 506. A semiconductor layer 516 corresponding to the gate 506 is then formed on the dielectric layer 514, and the boundary of the semiconductor layer 516 does not exceed the boundary of the gate 506. That is, the semiconductor layer 516 is “island-in” the gate 508. The materials and forming methods of the components in FIG. 5A are similar to those in FIGS. 4A to 4C, and the details are not iterated herein.

Referring to FIG. 5B, a dielectric layer 518 is formed on the substrate 500, and the dielectric layer 518 covers the semiconductor layer 516. The material of the dielectric layer 518 can be silicon oxide, silicon nitride, silicon oxynitride, a high-k material or a suitable organic material, and the forming method thereof includes performing a CVD process. Besides, the dielectric layer 504, the dielectric layer 514 and the dielectric layer 518 include the same or different materials.

Referring to FIG. 5C, a patterning step is performed to form two openings 520 and two openings 522 in the dielectric layer 504, the dielectric layer 514 and the dielectric layer 518. The openings 520 penetrate through the dielectric layer 504, the dielectric layer 514 and the dielectric layer 518, are disposed beside the gate 506 and respectively expose the doped regions 510 of the semiconductor layer 503. The openings 522 penetrate through the dielectric layer 518 and expose a portion of the upper surface of the semiconductor layer 516.

Referring to FIG. 5D, a metal layer 524 is formed on the substrate 500. The metal layer 524 fills in the openings 520 and the openings 522, so as to form a conductive plug 524a in each opening 520 and form a conductive plug 524b in each opening 522. Accordingly, the metal layer 524 contacts a portion of the upper surface of the semiconductor layer 516; that is, the conductive plugs 524b of the metal layer 524 contact the portion of the upper surface of the semiconductor layer 516. The material and forming method of the metal layer 524 have been described in the fourth embodiment, and the details are not iterated herein.

The semiconductor device of the fifth embodiment is thus completed. As similar to the case of the fourth embodiment, only five PEPs are required to fabricate the CMOS structure of the fifth embodiment. The structure of the fifth embodiment can serve as a CMOS inverter, wherein the lower structure is a P-type device, the upper structure is an N-type device, and the P-type device and the N-type device share the gate 506. In an embodiment, one of the conductive plugs 524a is electrically connected to one of the conductive plugs 524b (as shown in FIG. 5D), and the lower P-type device and the upper N-type device can be driven simultaneously. In another embodiment, the conductive plugs 524a are not electrically connected to the conductive plug 524b (as shown in FIG. 5D-1), and the lower P-type device and the upper N-type device are driven separately.

The semiconductor structure of the fifth embodiment is illustrated below with reference to FIGS. 5D and 5D-1. A semiconductor layer 503 is disposed on a substrate 500 and has a channel region 512 and two doped regions 510 located beside the channel region 512. A dielectric layer 504 is disposed on the substrate 500 and covers the semiconductor layer 503. A gate 506 is disposed on the dielectric layer 504, wherein the gate 506 corresponds to the channel region 512 of the semiconductor layer 503. A dielectric layer 514 is disposed on the substrate 500 and covers the gate 506. A semiconductor layer 516 is disposed on the dielectric layer 514 and corresponds to the gate 506, wherein the boundary of the semiconductor layer 516 does not exceed the boundary of the gate 506. A dielectric layer 518 is disposed on the substrate 500 and covers the semiconductor layer 516. Two conductive plugs 524a penetrate through the dielectric layer 504, the dielectric layer 514 and the dielectric layer 518, are disposed beside the gate 506 and respectively contact the doped regions 510 of the semiconductor layer 503. Two conductive plugs 524b penetrate through the dielectric layer 518 and contact the semiconductor layer 516. In an embodiment, one of the conductive plugs 524a is electrically connected to one of the conductive plugs 524b, as shown in FIG. 5D. In another embodiment, the conductive plugs 524a are not electrically connected to the conductive plugs 524b, as shown in FIG. 5D-1.

The fourth and fifth embodiments in which the structure includes a lower P-type device and an upper N-type device are provided for illustration purposes, and are not construed as limiting the present disclosure. It is appreciated by persons skilled in the art that the structure including a lower P-type device and an upper N-type device can be formed upon the process requirements.

### Sixth Embodiment

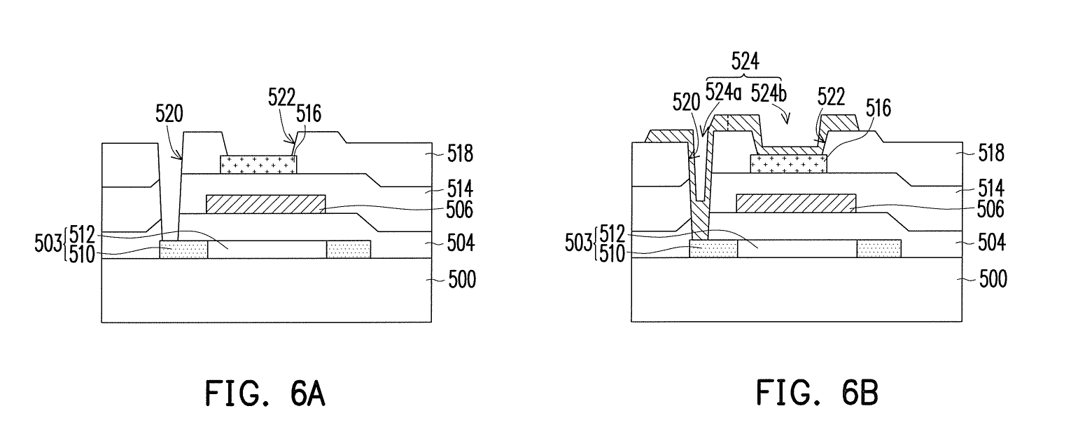

FIGS. 6A to 6B schematically illustrate cross-sectional views of a method of forming a semiconductor device according to a sixth embodiment of the disclosure. The sixth embodiment is similar to the fourth embodiment, the difference between them is illustrated in the following, and the similarity is not iterated herein.

First, an intermediate structure of FIG. 5B is provided. Thereafter, referring to FIG. 6A, a patterning step is performed to form one opening 520 and one opening 522 in the dielectric layer 504, the dielectric layer 514 and the dielectric layer 518. The opening 520 penetrates through the dielectric layer 504, the dielectric layer 514 and the dielectric layer 518, is disposed at one side of the gate 506 and exposes one of the doped regions 510 of the semiconductor layer 503. The opening 522 penetrates through the dielectric layer 518 and at least exposes a portion of the upper surface of the semiconductor layer 516. In an embodiment, the opening 522 exposes a portion of the upper surface of the semiconductor layer 516, as shown in FIG. 5B. In another embodiment (not shown), the opening 522 exposes the whole upper surface of the semiconductor layer 516.

Referring to FIG. 6B, a metal layer 524 is formed on the substrate 500. The metal layer 524 fills in the opening 520 and the opening 522, so as to form a conductive plug 524a in the opening 520 and form a conductive plug 524b in the opening 522. Accordingly, the metal layer 524 contacts a portion of the upper surface of the semiconductor layer 516. It is noted that the conductive plug 524a and the conductive plug 524b are electrically connected to each other. The material and forming method of the metal layer 524 have been described in the fourth embodiment, and the details are not iterated herein.

The semiconductor device of the sixth embodiment is thus completed. As similar to the case of the fourth embodiment, only five PEPs are required to fabricate the structure of the sixth embodiment. The structure of the sixth embodiment can serve as a stacked capacitor structure, wherein the lower capacitor and the upper capacitor are connected in parallel, so as to reduce the capacitor area in the circuit.

The semiconductor structure of the sixth embodiment is illustrated below with reference to FIG. 6B. The difference between the sixth and fifth embodiments lies in that the structure of the sixth embodiment only has one conductive plug 524a and one conductive plug 524b, and the conductive plug 524a is electrically connected to the conductive plug 524b.

In summary, in the present disclosure, only five PEPs are used to complete a semiconductor structure having an N-type device and a P-type device. Therefore, the number of processes is significantly reduced, the process cost is lower and the competitive advantage is achieved. Besides, the process temperature used in the method of the disclosure does not exceed 450° C. Accordingly, the method can be applied to a glass or a flexible substrate, so as to further enhance the variety and performance of the circuit design. In addition, the semiconductor structure having an N-type device and a P-type device of the disclosure can disposed in a horizontal or vertical arrangement, so as to broaden its application and increase its competitive advantage.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

1. A semiconductor device, comprising:
a substrate, having a first area and a second area;
a first semiconductor layer, disposed on the substrate in the first area and having a channel region and two doped region located beside the channel region;
a first dielectric layer, disposed on the substrate in the first area and in the second area and covering the first semiconductor layer;
a first gate and a second gate, disposed on the first dielectric layer respectively in the first area and in the second area, wherein the first gate corresponds to the channel region of the first semiconductor layer;
a second dielectric layer, disposed on the first dielectric layer in the first area and in the second area and covering the first gate and the second gate;
a second semiconductor layer, disposed on the second dielectric layer and corresponding to the second gate, wherein a boundary of the second semiconductor layer does not exceed a boundary of the second gate;
two first conductive plugs, penetrating through the first dielectric layer and the second dielectric layer, disposed beside the first gate and respectively contacting the doped regions of the first semiconductor layer; and
two contacts, located in the second area and contacting the second semiconductor layer.

2. The semiconductor device of claim 1, wherein the channel region is an undoped region.

3. The semiconductor device of claim 1, wherein the channel region is a doped region.

4. The semiconductor device of claim 1, further comprising a third dielectric layer disposed on the second dielectric layer in the first area and in the second area.

5. The semiconductor device of claim 4, wherein each contact is a metal pattern, the metal patterns are disposed respectively at two edges of a top surface of the second semiconductor layer and expose a central region of the top surface of the second semiconductor layer, and the third dielectric layer covers the metal patterns and an exposed top surface of the second semiconductor layer; and
wherein the third dielectric layer covers the first conductive plugs.

6. The semiconductor device of claim 4, wherein each contact is a second conductive plug penetrating through the third dielectric layer, and the first conductive plugs further penetrate through the third dielectric layer.

7. The semiconductor device of claim 6, wherein the first gate is electrically connected to one of the second conductive plugs.

8. The semiconductor device of claim 7, further comprising a third conductive plug penetrating through the second dielectric layer and the third dielectric layer and contacting the first gate, wherein the third conductive plug is electrically connected to one of the second conductive plugs.

9. The semiconductor device of claim 1, wherein the boundary of the second semiconductor layer is within the boundary of the second gate.

10. The semiconductor device of claim 1, wherein a material of the first semiconductor layer comprises low temperature polysilicon.

11. The semiconductor device of claim 1, wherein a material of the second semiconductor layer comprises metal oxide semiconductor.

12. The semiconductor device of claim 11, wherein the material of the second semiconductor layer comprises ZnO, InOx, SnOx, GaOx, AlOx or a combination thereof.

13. The semiconductor device of claim 1, wherein a material of the first gate and the second gate comprises Mo, W, Al, Ti or an alloy system containing one of said metals.

14. The semiconductor device of claim 1, wherein the first area is a P-type device area, and the second area is an N-type device area; or the first area is an N-type device area, and the second area is a P-type device area.

15. A semiconductor device, comprising:
a first semiconductor layer, disposed on a substrate and having a channel region and two doped regions located beside the channel region;
a first dielectric layer, disposed on the substrate and covering the first semiconductor layer;
a gate, disposed on the first dielectric layer, wherein the gate corresponds to the channel region of the first semiconductor layer;
a second dielectric layer, disposed on the first dielectric layer and covering the gate;
a second semiconductor layer, disposed on the second dielectric layer and corresponding to the gate, wherein a boundary of the second semiconductor layer does not exceed a boundary of the gate;
at least one first conductive plug, penetrating through the first dielectric layer and the second dielectric layer and contacting one of the doped regions of the first semiconductor layer; and
at least one contact, contacting the second semiconductor layer.

16. The semiconductor device of claim 15, wherein the channel region is an undoped region.

17. The semiconductor device of claim 15, wherein the channel region is a doped region.

18. The semiconductor device of claim 15, further comprising a third dielectric layer disposed on the second dielectric layer.

19. The semiconductor device of claim 18, wherein the at least one first conductive plug comprises two first conductive plugs penetrating through the first dielectric layer and the second dielectric layer, the first conductive plugs are disposed beside the gate and respectively contact the doped regions of the first semiconductor layer, and the third dielectric layer covers the first conductive plugs; and
wherein the at least one contact comprises two metal patterns, the metal patterns are disposed respectively at two edges of a top surface of the second semiconductor layer and expose a central region of the top surface of the second semiconductor layer, and the third dielectric layer covers the metal patterns and an exposed top surface of the second semiconductor layer.

20. The semiconductor device of claim 19, wherein one of the first conductive plugs is electrically connected to one of the metal patterns.

21. The semiconductor device of claim 19, wherein the first conductive plugs are not electrically connected to the metal patterns.

22. The semiconductor device of claim 18, wherein the at least one first conductive plug comprises two first conductive plugs penetrating through the first dielectric layer, the second dielectric layer and the third dielectric layer, the first conductive plugs are disposed beside the gate and respectively contact the doped regions of the first semiconductor layer; and
wherein the at least one contact comprises two second conductive plugs penetrating through the third dielectric layer.

23. The semiconductor device of claim 22, wherein one of the first conductive plugs is electrically connected to one of the second conductive plugs.

24. The semiconductor device of claim 22, wherein the first conductive plugs are not electrically connected to the second conductive plugs.

25. The semiconductor device of claim 18, wherein the contact is a second conductive plug penetrating through the third dielectric layer, the first conductive plug further penetrates through the third dielectric layer, and the second conductive plug is electrically connected to the first conductive plug.

26. The semiconductor device of claim 15, wherein the boundary of the second semiconductor layer is within the boundary of the gate.

27. The semiconductor device of claim 15, wherein a material of the first semiconductor layer comprises low temperature polysilicon.

28. The semiconductor device of claim 15, wherein a material of the second semiconductor layer comprises metal oxide semiconductor.

29. The semiconductor device of claim 28, wherein the material of the second semiconductor layer comprises ZnO, InOx, SnOx, GaOx, AlOx or a combination thereof.

30. The semiconductor device of claim 15, wherein a material of the gate comprises Mo, W, Al, Ti or an alloy system containing one of said metals.

31. A method of forming a semiconductor device, comprising:
providing a substrate, the substrate having a first area and a second area;
forming a first semiconductor layer on the substrate in the first area;
forming a first dielectric layer on the substrate in the first area and in the second area, the first dielectric layer covering the first semiconductor layer;
forming a first gate and a second gate on the first dielectric layer respectively in the first area and in the second area;
performing an ion implantation process to the first semiconductor layer by using the first gate as a mask, so as to form two doped regions in the first semiconductor layer;
forming a second dielectric layer on the substrate in the first area and in the second area, the second dielectric layer covering the first gate and the second gate;
forming a second semiconductor layer on the second dielectric layer, wherein the second semiconductor layer corresponds to the second gate, and a boundary of the second semiconductor layer does not exceed a boundary of the second gate;
performing a patterning step to form two first openings in the first dielectric layer and the second dielectric layer, wherein the first openings respectively expose the doped regions of the first semiconductor layer; and
forming a metal layer on the substrate, wherein the metal layer fills in the first openings to form a first conductive plug in each first opening, and the metal layer contacts a portion of an upper surface of the second semiconductor layer.

32. The method of claim 31, wherein the metal layer has two metal patterns, and the metal patterns respectively cover two edges of a top surface of the second semiconductor layer while expose a central region of the top surface of the second semiconductor layer.

33. The method of claim 32, further comprising forming a third dielectric layer on the second dielectric layer in the first area and in the second area, wherein the third dielectric layer covers the metal patterns and an exposed top surface of the second semiconductor layer, and covers the first conductive plugs.

34. The method of claim 31, further comprising, after forming the second semiconductor layer on the second dielectric layer and before performing the patterning step, forming a third dielectric layer on the second dielectric layer in the first area and in the second area, wherein the first openings penetrate through the first dielectric layer, the second dielectric layer and the third dielectric layer;
wherein the patterning step further comprises forming two second openings in the third dielectric layer, and the second openings expose a portion of an upper surface of the second semiconductor layer; and
wherein the metal layer further fills in the second openings, so as to form a second conductive plug in each second opening.

35. The method of claim 34, wherein the first gate is electrically connected to one of the second conductive plugs.

36. The method of claim 35, wherein the patterning step further comprises forming a third opening in the second dielectric layer and the third dielectric layer, and the third opening exposes a portion of the first gate; and
wherein the metal layer further fills in the third opening to form a third conductive plug in the third opening, and the third conductive plug is electrically connected to one of the second conductive plugs.

37. The method of claim 31, wherein the boundary of the second semiconductor layer is within the boundary of the second gate.

38. The method of claim 31, wherein a material of the first semiconductor layer comprises low temperature polysilicon.

39. The method of claim 38, wherein a method of forming the first semiconductor layer comprises:
forming an amorphous silicon layer on the substrate in the first area and in the second area;
performing a crystallization process to the amorphous silicon layer so as to form a polysilicon layer; and
patterning the polysilicon layer.

40. The method of claim 39, wherein the crystallization process comprises an excimer laser annealing (ELA) process and a metal induced crystallization (MIC) process.

41. The method of claim 31, wherein a material of the second semiconductor layer comprises metal oxide semiconductor.

42. The method of claim 41, wherein the material of the second semiconductor layer comprises ZnO, InOx, SnOx, GaOx, AlOx or a combination thereof

43. The method of claim 31, wherein a material of the first gate and the second gate comprises Mo, W, Al, Ti or an alloy system containing one of said metals.

44. The method of claim 31, wherein a process temperature does not exceed 450° C.

45. The method of claim 31, wherein the first area is a P-type device area, and the second area is an N-type device area; or the first area is an N-type device area, and the second area is a P-type device area.

46. A method of forming a semiconductor device, comprising:
forming a first semiconductor layer on a substrate;
forming a first dielectric layer on the substrate, the first dielectric layer covering the first semiconductor layer;
forming a gate on the first dielectric layer;
performing an ion implantation process to the first semiconductor layer by using the gate as a mask, so as to form two doped regions in the first semiconductor layer;
forming a second dielectric layer on the substrate, the second dielectric layer covering the gate;
forming a second semiconductor layer on the second dielectric layer, wherein the second semiconductor layer corresponds to the gate, and a boundary of the second semiconductor layer does not exceed a boundary of the gate;
performing a patterning step to form at least one first opening in the first dielectric layer and the second dielectric layer, the first opening exposing one of the doped regions of the first semiconductor layer; and
forming a metal layer on the substrate, wherein the metal layer fills in the first opening to form a first conductive plug in the first opening, and the metal layer at least contacts a portion of an upper surface of the second semiconductor layer.

47. The method of claim 46, wherein the metal layer has two metal patterns, and the metal patterns are disposed respectively at two edges of a top surface of the second semiconductor layer while expose a central region of the top surface of the second semiconductor layer.

48. The method of claim 47, further comprising forming a third dielectric layer on the second dielectric layer, wherein the third dielectric layer covers the metal patterns and an exposed top surface of the second semiconductor layer, and covers the at least one first conductive plug.

49. The method of claim 46, further comprising, after forming the second semiconductor layer on the second dielectric layer and before performing the patterning step, forming a third dielectric layer on the second dielectric layer in the first area and in the second area, wherein the at least one first opening comprises two first openings penetrating through the first dielectric layer, the second dielectric layer and the third dielectric layer, the first openings are disposed beside the gate and respectively expose the doped regions of the first semiconductor layer;
wherein the patterning step further comprises forming two second openings in the third dielectric layer, and the second openings expose a portion of an upper surface of the second semiconductor layer; and
wherein the metal layer further fills in the second openings to form a second conductive plug in each second opening.

50. The method of claim 49, wherein one of the first conductive plugs is electrically connected to one of the second conductive plugs.

51. The method of claim 49, wherein the first conductive plugs are not electrically connected to the second conductive plugs.

52. The method of claim 46, further comprising, after forming the second semiconductor layer on the second dielectric layer and before performing the patterning step, forming a third dielectric layer on the second dielectric layer in the first area and in the second area, wherein the first opening penetrates through the first dielectric layer, the second dielectric layer and the third dielectric layer;
wherein the patterning step further comprises forming a second opening in the third dielectric layer, and the second opening exposes a portion of an upper surface of the second semiconductor layer; and
wherein the metal layer further fills in the second opening to form a second conductive plug in the second opening, and the second conductive plug is electrically connected to the first conductive plug.

53. The method of claim 46, wherein the boundary of the second semiconductor layer is within the boundary of the gate.

54. The method of claim 46, wherein a material of the first semiconductor layer comprises low temperature polysilicon.

55. The method of claim 54, wherein a method of forming the first semiconductor layer comprises:
forming an amorphous silicon layer on the substrate;
performing a crystallization process to the amorphous silicon layer, so as to form a polysilicon layer; and
patterning the polysilicon layer.

56. The method of claim 55, wherein the crystallization process comprises an excimer laser annealing (ELA) process and a metal induced crystallization (MIC) process.

57. The method of claim 46, wherein a material of the second semiconductor layer comprises metal oxide semiconductor.

58. The method of claim 57, wherein the material of the second semiconductor layer comprises ZnO, InOx, SnOx, GaOx, AlOx or a combination thereof

59. The method of claim 46, wherein a material of the gate comprises Mo, W, Al, Ti or an alloy system containing one of said metals.

60. The method of claim 46, wherein a process temperature does not exceed 450° C.
